(19) United States
(12) Patent Application Publication
(10) Pub. No.: US 2005/0151211 A1
(43) Pub. Date: Jul. 14, 2005

(54) Semiconductor device, and method and apparatus for manufacturing the same

(75) Inventors: Mitsuaki Hori, Kawasaki (JP); Hiroyuki Ohta, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 10/851,212

(22) Filed: May 24, 2004

(30) Foreign Application Priority Data
Jan. 6, 2004 (JP) 2004-001011

(51) Int. Cl. H01L 29/76

(52) U.S. Cl. 257/411

(57) ABSTRACT

A SiO₂ film is formed on a semiconductor substrate. Then, a SiN film is formed on the SiO₂ film. In this event bis (tertiary butyl amino) silane and NH₃ are used as a material gas, and the film forming temperature is set to 600° C. or lower.

### CROSS-REFERENCE TO RELATED APPLICATIONS

This application is based upon and claims the benefit of priority from the prior Japanese Patent Application No. 2004-001011, filed on Jan. 6, 2004, the entire contents of which are incorporated herein by reference.

### BACKGROUND OF THE INVENTION

1. Field of the Invention

The present invention relates to a semiconductor device including a gate insulation film in a layered structure, and a method and an apparatus for manufacturing the same.

2. Description of the Related Art

In recent years, thinning of a gate insulation film has been on progress, with which a reduction in leak current has been required. Hence, trials are made to layer on a silicon oxide film (SiO₂ film) a silicon nitride film (SiN film), which has a dielectric constant higher than that of the SiO₂ film, and to nitride the surface of a SiO₂ film by a remote plasma method to thereby form a SiON film thereon.

In a method for layering the SiN film, dichlorosilane (DCS) or trichlorosilane (TCS) and NH₃ are used as a material gas. However, when using this material gas, the SiN film is not uniformly formed on the SiO₂ film. Therefore, the surface of the SiO₂ film is thermally nitrided at about 700° C. to 850° C. before the formation of the SiN film to thereby form a SiON film thereon. However, when this method is employed to try to obtain a gate insulation film with a thickness of about 1.2 nm, a large amount of nitrogen reaches not only the surface of the SiO₂ film but also a silicon substrate during nitridation, so that a threshold value Vth of a field effect transistor varies in the negative direction. Further, there also is a problem that the mobility of holes in a channel decreases.

On the other hand, in the method for nitridation by the remote plasma method, when control is conducted to decrease the nitrogen concentration in the vicinity of the surface of the silicon substrate to avoid the above-described disadvantage, the nitridation of the SiO₂ film is not enough, resulting in insufficient effect to reduce the leak current. Besides, when trying to sufficiently reduce the leak current, the problem of the variation in threshold value and the decrease in mobility is not solved as in the above-described layering.

In addition, as a method for forming a nitride film, a method using bis(t-butylamino) silane is also disclosed (Patent Documents 3 and 4).

Prior arts are disclosed in Patent Document 1 (Japanese Patent Application Laid-open No. Hei 7-50347), Patent Document 2 (Translated National Publication of Patent Application No. 2002-523897), the Patent Document 3 (Japanese Patent No. 2962417), and the Patent Document 4 (Japanese Patent No. 3055123).

### SUMMARY OF THE INVENTION

It is an object of the present invention to provide a semiconductor device capable of decreasing leak current while suppressing a variation in threshold value and a decrease in mobility, and a method and an apparatus for manufacturing the same.

As a result of earnest studies to solve the above problems, the present inventor has devised various aspects of the invention described below.

In a method for manufacturing a semiconductor device according to the present invention, a gate insulation film is formed over a semiconductor substrate, and thereafter a conductive film is formed over the gate insulation film. When forming the gate insulation film, a first insulation film is formed, and thereafter over the first insulation film a second insulation film composed of a nitride is formed using a material gas containing carbon.

According to this method, a semiconductor device is obtained which comprises a semiconductor substrate, a gate insulation film formed over the semiconductor substrate, and a gate electrode formed over the gate insulation film, wherein the gate insulation film comprises a first insulation film, and a second insulation film formed over the first insulation film and composed of a nitride containing carbon, for example.

Further, an apparatus for manufacturing a semiconductor device according to the present invention is suitable for implementing the above-described manufacturing method. The apparatus comprises: a carrier carrying a semiconductor substrate in an atmosphere isolated from atmospheric air; a first insulation film former forming a first insulation film over the semiconductor substrate; a second insulation film former forming a second insulation film composed of a nitride using a material gas containing carbon over the first insulation film; and a heater performing post-annealing on the first and second insulation films. Further, the first insulation film former, the second insulation film former, and the heater are connected to the carrier unit.

### BRIEF DESCRIPTION OF THE DRAWINGS

FIGS. 1A to 1C are cross-sectional views showing, in the order of steps, a method for manufacturing a semiconductor device according to an embodiment of the present invention;

FIG. 2 is an illustration showing the change of the structural formula of BTBAS;

FIGS. 3A and 3B are views showing the appearance of growth of a silicon nitride film;

FIG. 4 is a schematic view showing an apparatus for manufacturing a semiconductor device;

FIG. 5 is a cross-sectional view showing a method for manufacturing a semiconductor device using BTBAS;

FIG. 6 is a graph showing the nitrogen profiles of samples fabricated by the method shown in FIG. 5;

FIGS. 7A and 7B are cross-sectional views showing a method for manufacturing a semiconductor device using DCS;

FIG. 8 is a graph showing the nitrogen profiles of a sample fabricated by the method shown in FIGS. 7A and 7B;

FIGS. 9A and 9B are cross-sectional views showing a method for manufacturing a semiconductor device using a remote plasma method;

FIG. 10 is a graph showing the nitrogen profiles of a sample fabricated by the method shown in FIGS. 9A and 9B;

FIG. 11 is a graph showing the nitrogen profiles of gate insulation films fabricated by various methods;

FIGS. 12A and 12B are graphs showing the carbon profiles of gate insulation films;

FIGS. 13A and 13B are graphs showing the mobilities of samples fabricated by various methods;

FIGS. 14A and 14B are graphs showing the leak currents of samples fabricated by various methods;

FIG. 15 is a graph showing differences in threshold value among samples fabricated by various methods;

FIG. 16 is a graph showing the relation between conditions of post-annealing and nitrogen profile;

FIG. 17 is a graph showing each TDDB life of a comparative example and an example of the present invention; and

FIG. 18 is a graph showing each NBTI life of a comparative example and an example of the present invention.

### DETAILED DESCRIPTION OF THE PREFERRED EMBODIMENTS

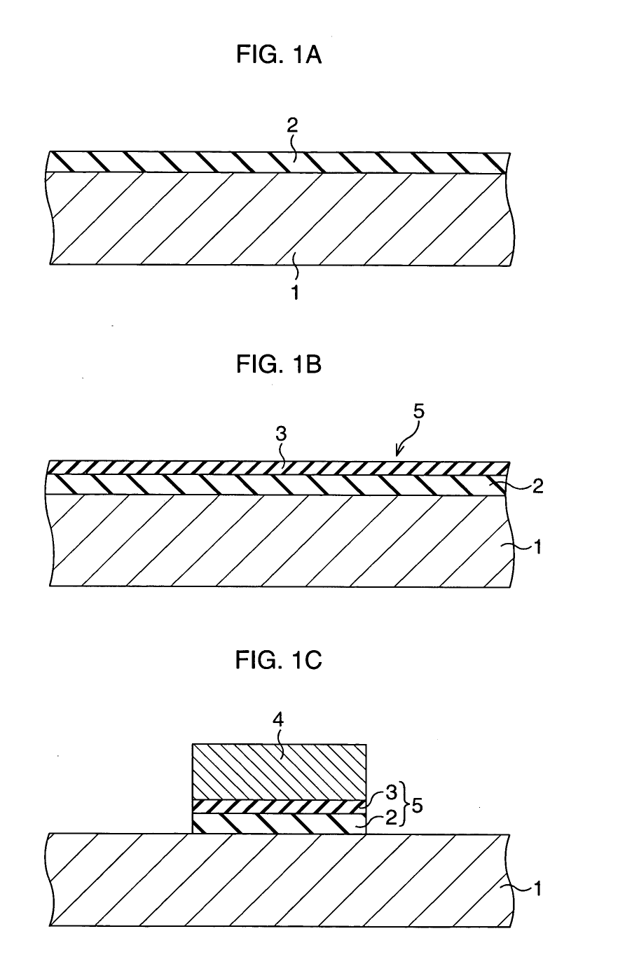

Hereinafter, embodiments of the present invention will be concretely descried with reference to the accompanying the drawings. Note that, for convenience, a structure of a semiconductor device will be described here in conjunction with a method for manufacturing the same. FIGS. 1A to 1C are cross-sectional views showing, in the order of steps, a method for manufacturing a semiconductor device according to an embodiment of the present invention.

In this embodiment, as shown in FIG. 1A, a silicon oxide film (SiO₂ film) 2 is first formed as a first insulation film on a surface of a semiconductor substrate 1 such as a silicon substrate, for example, by thermal oxidation. Then, a SiN film 3 is formed as a second insulation film on the SiO₂ film 2 by a CVD method. In this event, Bis (Tertiary Butyl Amino) Silane, which is contains carbon, and NH₃ are used as a material gas. Hereinafter, Bis (Tertiary Butyl Amino) Silane is referred to as BTBAS. Further, the film forming temperature is, for example, 600° C. or lower. Thus, a gate insulation film 5 is formed which is composed of the SiO₂ film 2 and the SiN film 3. Note that, in addition to BTBAS, HMDS (hexamethyldisilazane), TSA (trisilylamine), TMS (trimethylsilane) may be used as the material gas containing carbon. The thickness (physical film thickness) of the gate insulation film 5 is, for example, about 1.2 nm. Subsequently, a conductive film such as a polysilicon film is formed on the SiN film 3 and patterned to form a gate electrode 4 as shown in FIG. 1C. Thereafter, source/drain diffusion layers, interlayer insulation films, wirings, and so on are formed to complete a semiconductor device. It should be noted that the thickness of the SiO₂ film 2 is, for example, 0.4 nm to 10 nm, and the thickness of the SiN film 3 is, for example, 0.1 nm to 3.0 nm.

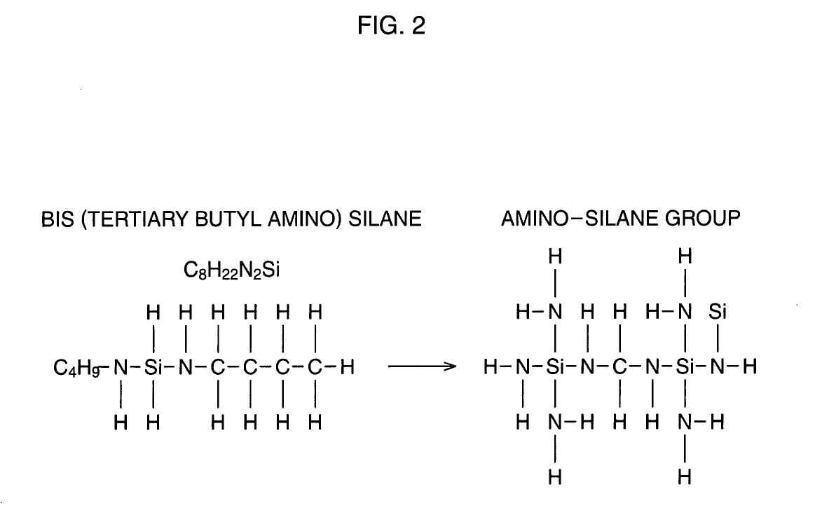

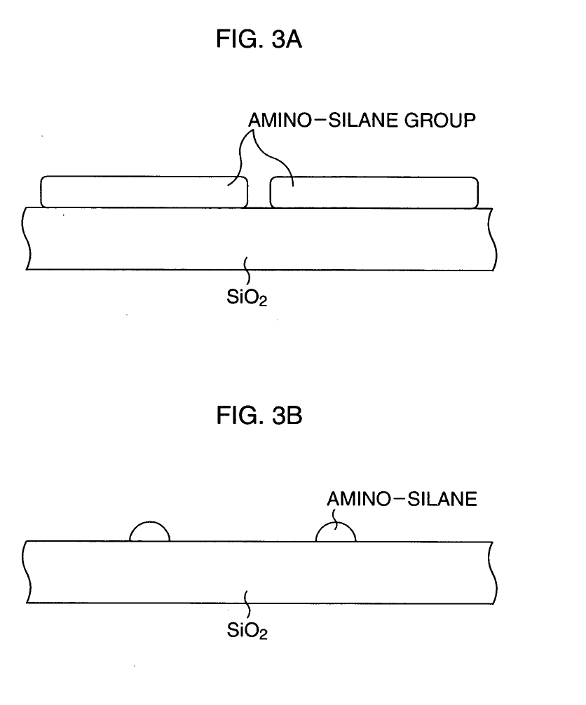

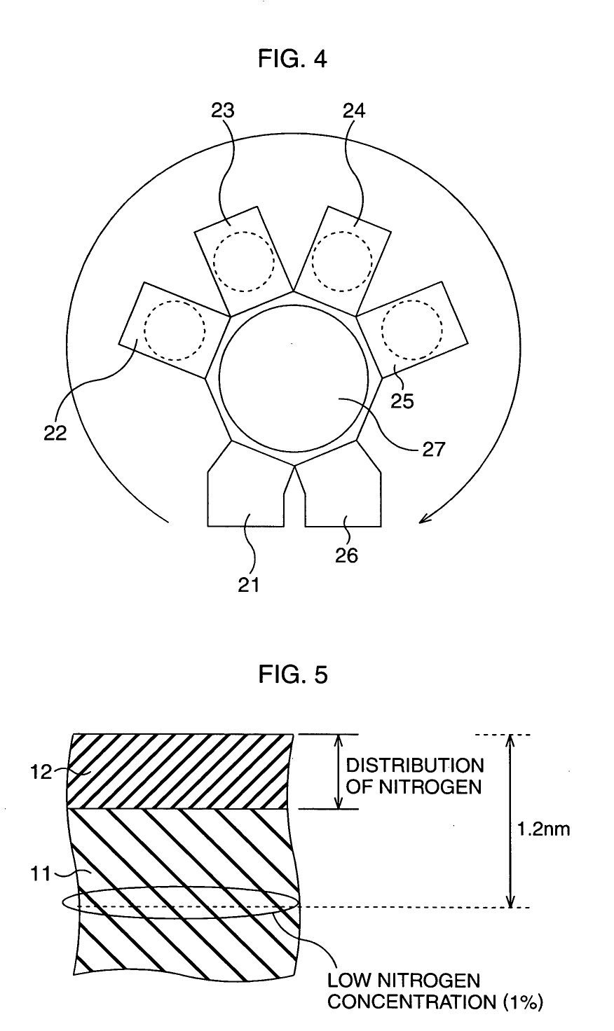

The molecular formula of BTBAS is C₈H₂₂N₂Si, and the structural formula thereof is as shown in FIG. 2. In the formation of the SiN film 3 using BTBAS, the amino-silane group polymer as shown in FIG. 2 is a film forming precursor. For this reason, the SiN film 3 is formed to contain a small amount of carbon and to be uniform on the SiO₂ film 2, which is a base film, as shown in FIG. 3A. Therefore, it is unnecessary to perform thermal nitridation before the formation of the SiN film 3, thus enabling avoidance of variation in threshold value and decrease in mobility accompanying the thermal nitridation.

In contrast to the above, when the DCS or TCS is used as the material gas as in the prior art to form the SiN film on the SiO₂ film without thermal nitridation, a simple substance of amino-silane is the film forming precursor. Therefore, the SiN film is nonuniformly formed as shown in FIG. 3B. Accordingly, thermal nitridation is necessary before the formation of the SiN film.

Thus, according to the present embodiment, it is possible to form the SiN film 3 uniformly on the SiO₂ film without performing thermal nitridation, which diffuses nitrogen up to the surface of the semiconductor substrate 1. This will properly reduce the leak current while avoiding disadvantages (the variation in threshold value and the decrease in mobility) accompanying the diffusion of nitrogen.

It should be noted that it is preferable to perform post-annealing, for example, at 900° C. to 1100° C. after the formation of the SiN film 3. Examples of the atmosphere in this event include, for example, a N₂ atmosphere, a NO atmosphere, and an O₂ atmosphere. In the post-annealing, it is particularly preferable to perform a first annealing in the NO atmosphere or O₂ atmosphere and then perform a second annealing in the N₂ atmosphere. The annealing temperature is, for example, 1000° C.

Next, an apparatus for manufacturing a semiconductor device suitable for the above-described embodiment will be described. FIG. 4 is a schematic view of the apparatus for manufacturing a semiconductor device. In this manufacturing apparatus, a carry-in port 21, a base film forming section (first insulation film former) 22, a nitride film forming section (second insulation film former) 23, a post-annealing section (heater) 24, a cooling section 25, and a carry-out port 26 are connected around a carrier system (carrier) 27. The inside of the carrier system 27 is brought into a controllable atmosphere such as a N₂ atmosphere isolated from atmospheric air. The carry-in port 21 and the carry-out port 26 are, for example, load lock chambers.

When manufacturing a semiconductor device using the manufacturing apparatus described above, first, a semiconductor substrate is put into the carrier system 27 via the carry-in port 21. Then, in the base film forming section 22, a SiO₂ film is formed as a base film on the surface of the semiconductor substrate. Subsequently, the semiconductor substrate is carried using the carrier system 27 to the nitride film forming section 23 to have a SiN film formed using BTBAS in the nitride film forming section 23. Thereafter, the semiconductor substrate is carried to the post-annealing section 24 using the carrier system 27 to be subjected to post-annealing at about 1000° C. in the post-annealing section 24. Subsequently, the semiconductor substrate is carried to the cooling section 25 using the carrier system 27 to be cooled in the cooling section 25. Then, the semiconductor substrate is carried using the carrier system 27 to the carry-out port 26 to be taken out therefrom.

In the apparatus for manufacturing a semiconductor device described above, processing from the formation of the SiO₂ film to the post-annealing can be performed without a contact of the semiconductor substrate with atmospheric air. Therefore, unnecessary chemical reaction or the like can be suppressed which affects characteristics.

Note that the first insulation film is not limited to the SiO₂ film, but a SiON film may be formed when its nitrogen concentration can be controlled. Alternatively, it is also adoptable that after the formation of the first insulation film, a high dielectric constant film such as any of hafnium oxide film, zirconium oxide film, aluminum oxide film, ZrAl oxide film, lanthanum oxide film, tantalum oxide film, titanium oxide film, and yttrium oxide film is formed on the first insulation film, and a second insulation film is formed thereon to thereby form a gate insulation film in a three-layer structure.

Next, results of various experiments carried out by the present inventors will be explained.

### EXAMPLE 1

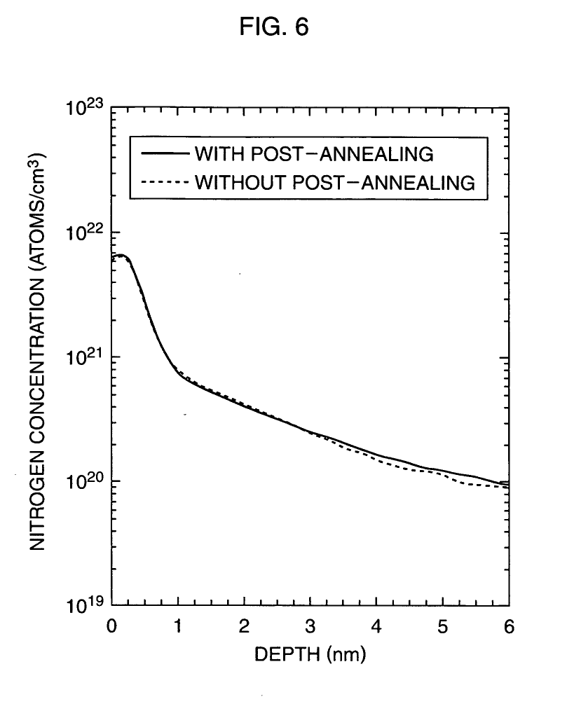

In the first experiment, samples were prepared by four kinds of methods and their nitrogen profiles were measured by SIMS. Two out of the four kinds of methods are manufacturing methods according to examples of the present invention, and a SiN film 12 with a thickness of 0.2 nm was formed on a SiO₂ film 11 as shown in FIG. 5 by the CVD method using BTBAS and NH₃ as a material gas in each of these two manufacturing methods. For one of them, its nitrogen profile was measured after performance of post-annealing (N₂ atmosphere) at 1050° C., and for the other, its nitrogen profile was measured without performance of post-annealing. As results of the above, as shown in FIG. 6, steep distributions were obtained both in the sample (broken line) for which the post-annealing was performed and the sample (solid line) for which no post-annealing was performed. In analysis of the two samples, the nitrogen concentration was as low as about 1% at a position with a depth of 1.2 nm (physical depth) from the surface of the SiN film 12, that is, a position corresponding to the interface between the silicon substrate and the SiO₂ film as shown in FIG. 5.

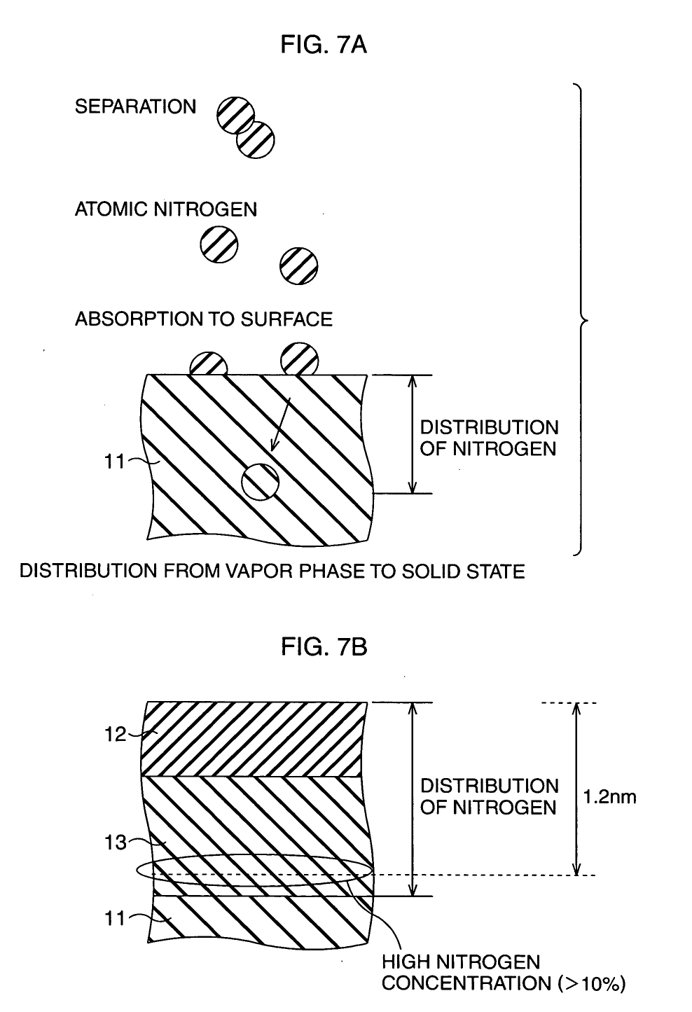

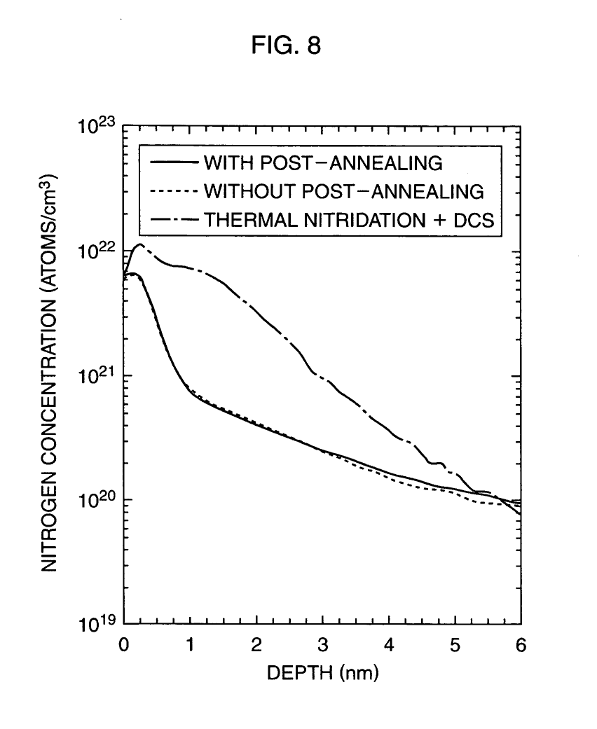

Further, in another kind of manufacturing method, as shown in FIGS. 7A and 7B, after the surface of the SiO₂ film 12 was thermally nitrided at 850° C. using NH₃ to form a SiON film 13, a SiN film 12 with a thickness of 0.2 nm was formed thereon by the CVD method using the DCS and NH₃ as a material gas. Then, when the nitrogen profile of this sample was measured, a gentle distribution (one-dotted chain line) was obtained as shown in FIG. 8. In analysis of this sample, the nitrogen concentration exceeded 10% that was extremely high at a position with a depth of 1.2 nm from the surface of the SiN film 12 as shown in FIG. 7B. This indicates that the threshold value varies with a decrease in the mobility of holes. Note that the solid line and the broken line in FIG. 8 show the same as those in FIG. 6.

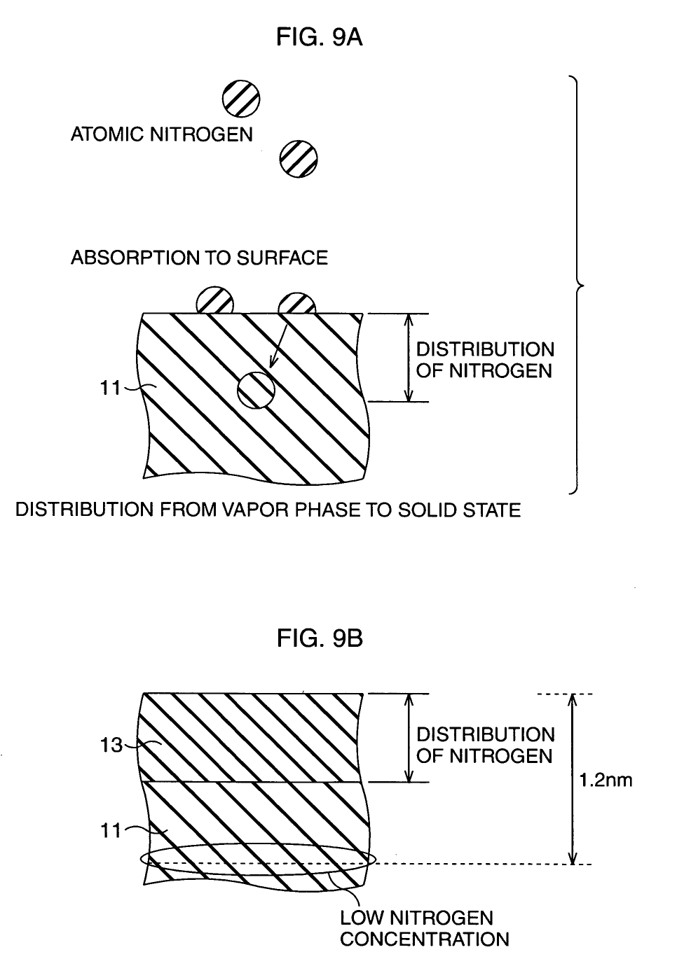

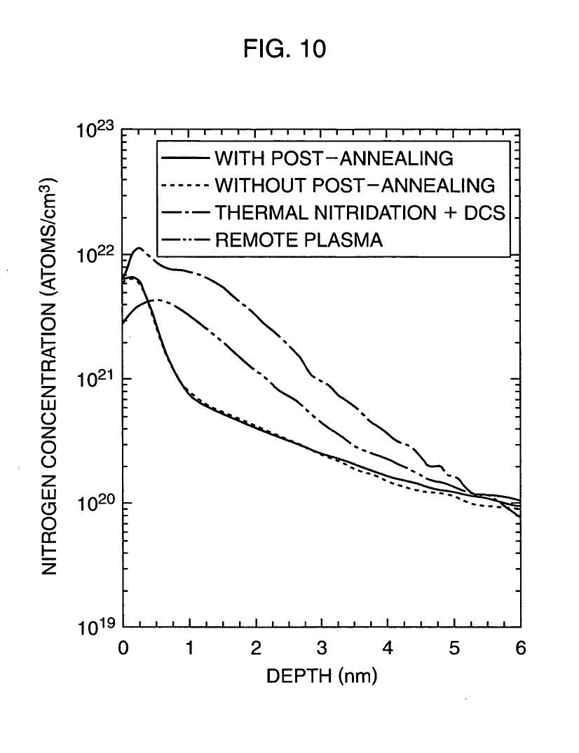

In the other one kind of manufacturing method, as shown in FIGS. 9A and 9B, the surface of the SiO₂ film 11 was nitrided by a remote plasma method to form a SiON film 13. Then, when the nitrogen profile of this sample was measured, a gentle distribution (two-dotted chain line) was obtained as shown in FIG. 10. In analysis of this sample, the nitrogen concentration was low at a position with a depth of 1.2 nm from the surface of the SiON film 13 as shown in FIG. 9B. However, also on the surface of the SiON film 13, the nitrogen concentration was low. This indicates that the leak current cannot be sufficiently reduced. Note that the solid line, the broken line, and the one-dotted chain line in FIG. 10 show the same as those in FIG. 8.

### EXAMPLE 2

In the second experiment, samples were fabricated by various kinds of methods as in the first experiment, and their nitrogen profiles were measured. Fabrication conditions (manufacturing methods) of the samples are shown in Table 1. Note that “Optical film thickness of insulation film” in Table 1 shows the values of optical film thickness measured with the refractive index n fixed to 2 using an ellipsometer. The measurement region is infrared region (short wavelength).

TABLE 1

| | | | Optical film |
|---|---|---|---|
| | | Formation | thickness of |
| Condition | Thickness of | condition of | insulation |
| No. | SiO₂ film | nitride film | film |
| 21 | 0.85 nm | Using BTBAS | 2.05 nm |
| 22 | 0.85 nm | Using BTBAS | 1.42 nm |
| 23 | 0.85 nm | Remote | 1.19 nm |
| | | plasma | |
| 24 | 0.85 nm | Thermal | 1.11 nm |
| | | nitridation | |
| | | (Using NO) | |
| 25 | 0.90 nm | Using DCS | 1.51 nm |
| 26 | 0.90 nm | Using DCS | 1.34 nm |

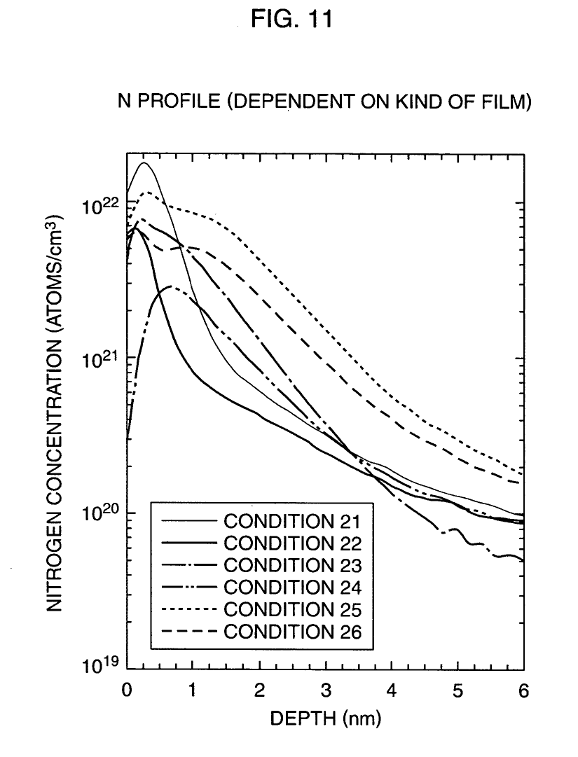

The nitrogen profiles of these samples are shown in FIG. 11. In FIG. 11, a thin solid line shows the nitrogen profile of the sample fabricated on the condition 21 (example), a thick solid line shows the nitrogen profile of the sample fabricated on the condition 22 (example), a one-dotted chain line shows the nitrogen profile of the sample fabricated on the condition 23 (comparative example), a two-dotted chain line shows the nitrogen profile of the sample fabricated on the condition 24 (comparative example), a dot line shows the nitrogen profile of the sample fabricated on the condition 25 (comparative example), and a broken line shows the nitrogen profile of the sample fabricated on the condition 26 (comparative example).

As shown in FIG. 11, on the conditions 21 and 22 according to examples of the present invention, steep nitrogen profiles were obtained, but the nitrogen concentrations gradually changed on the conditions 23, 24, 25, and 26 according to comparative examples.

### EXAMPLE 3

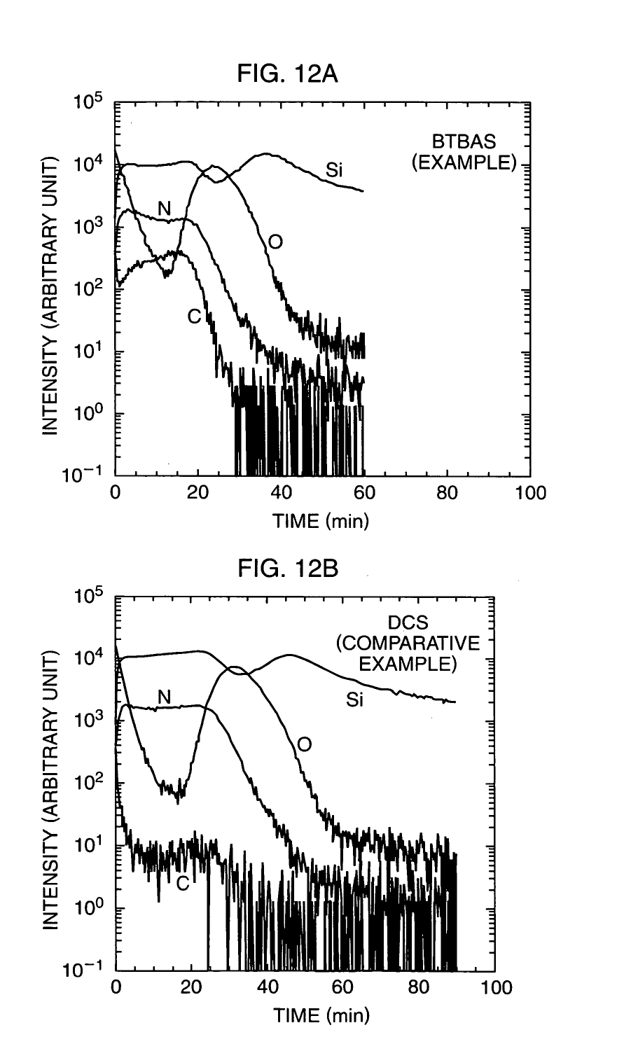

In the third experiment, samples were fabricated by two kinds of methods and their carbon profiles were measured by SIMS. One method is a manufacturing method according to an example of the present invention, and a SiN film was formed on a SiO₂ film as in the first experiment by the CVD method using the BTBAS and NH₃ as a material gas in this manufacturing method. The other method is a manufacturing method according to a comparative example, in which the surface of a SiO₂ film was thermally nitrided to form a SiON film and then a SiN film was formed thereon by the CVD method using the DCS and NH₃ as a material gas. Then, the carbon profiles of these samples were measured. As a result of this, in an example as shown in FIG. 12A, carbon was detected in the vicinity of the surface of the insulation film, that is, at a portion corresponding to the SiN film, whereas no carbon was detected over the entire insulation film in a comparative example as shown in FIG. 12B. This indicates that the SiN film formed using BTBAS contains carbon as shown in FIG. 2 and FIG. 3.

### EXAMPLE 4

In the fourth experiment, the relation between the conditions of post-annealing and the mobility was examined. Specifically, six kinds of samples were fabricated as in the first experiment, and their GmX Teff were measured. The fabrication conditions (manufacturing methods) of the samples are shown in Table 2.

TABLE 2

| | Formation | |
|---|---|---|
| Condition | condition of | |
| No. | nitride film | Post-annealing |
| 41 | Using BTBAS | 1st time: |
| | | NO atmosphere, |
| | | 2nd time: |
| | | N₂ atmosphere |
| 42 | Using BTBAS | 1st time: |
| | | O₂ atmosphere, |
| | | 2nd time: |
| | | N₂ atmosphere |
| 43 | Using BTBAS | Only one time in |
| | | N₂ atmosphere |
| 44 | Using BTBAS | No |
| 45 | Remote plasma | 1st time: |
| | | O₂ atmosphere, |
| | | 2nd time: |
| | | N₂ atmosphere |
| 46 | Using DCS | 1st time: |
| | | O₂ atmosphere, |
| | | 2nd time: |
| | | N₂ atmosphere |

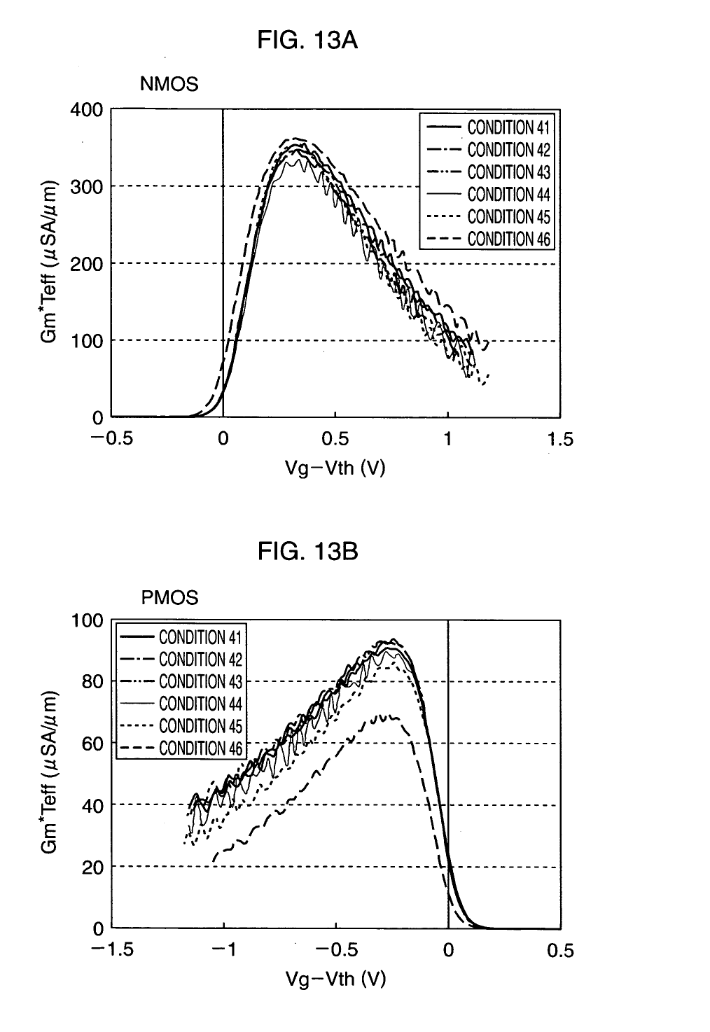

The measurement results on these samples are shown in FIGS. 13A and 13B. FIG. 13A shows the mobility of electrons in an NMOS transistor, and FIG. 13B shows the mobility of holes in a PMOS transistor.

In the NMOS transistor, as shown in FIG. 13A, there was no big difference, but the mobilities of electrons on the conditions 41, 42, 43, and 44 according to examples were higher than the mobility on the condition 45 according to a comparative example.

In the PMOS transistor, as shown in FIG. 13B, the mobilities of holes on the conditions 41, 42, 43, and 44 were significantly higher than the mobility on the condition 46 according to a comparative example. Further, the mobilities on the conditions 41, 42, 43, and 44 were slightly high as compared even with the mobility on the condition 45.

In both the NMOS transistor and PMOS transistor, in comparison between the condition 44, in which post-annealing was not performed, and the conditions 41, 42, and 43, in which the post-annealing was performed, a higher mobility was obtained on the conditions 41, 42, and 43 than on the condition 44.

### EXAMPLE 5

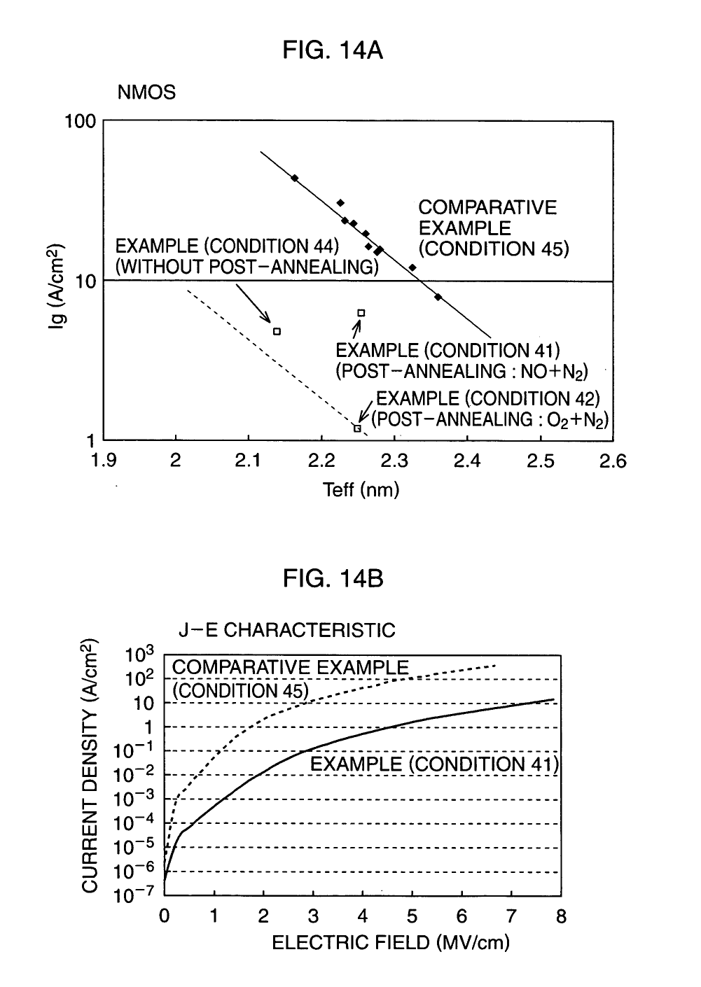

In the fifth experiment, the relation between the conditions of post-annealing and the leak current was examined. Specifically, the gate current was measured for the samples fabricated on the conditions 41, 42, 44, and 45 in the fourth experiment. The measurement results on these samples are shown in FIGS. 14A and 14B.

As shown in FIG. 14A, a leak current lower than that of the conventional example was obtained in each example. Further, when the relation between the electric field and the current density was measured on the conditions 41 and 45, the current density was lower on the condition 41 than on the condition 45 as shown in FIG. 14B.

### EXAMPLE 6

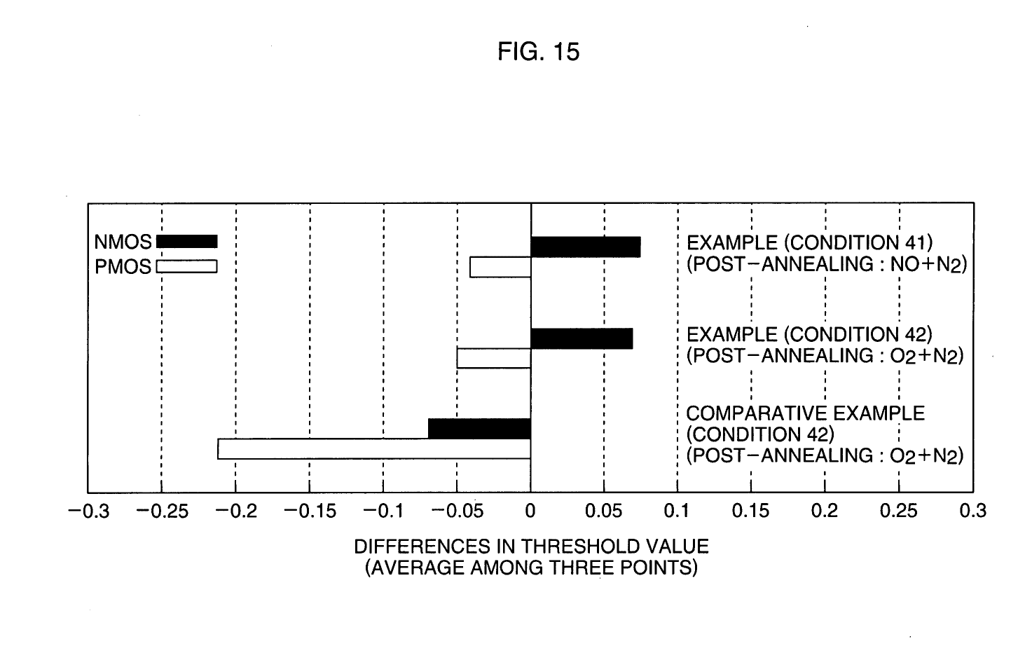

In the sixth experiment, the relation between the conditions of post-annealing and the threshold value was examined. Specifically, the threshold value was measured for the samples fabricated on the conditions 41, 42, 45, and 46 in the fourth experiment. It should be noted that on the condition 46, the post annealing in the O₂ atmosphere and the post-annealing in the N₂ atmosphere were performed after the SiN film was formed for comparison. Besides, in each sample, the gate length was 1.04 μm, and the gate width was 20 μm. The measurement results on these samples are shown in FIG. 15. FIG. 15 shows the relative value (shift amount) of the threshold value of each sample when using as a reference voltage (0V) the threshold value of the sample fabricated on the condition 45 (remote plasma nitridation treatment, formation of a nitride film by annealing using O₂ and annealing using N₂).

As shown in FIG. 15, the threshold value shifted in the negative direction both in the NMOS transistor and the PMOS transistor on the condition 46 according to a comparative example as compared to the condition 45 using the plasma nitridation treatment. In short, the threshold value became smaller on the condition 46 than that on the condition 45. In particular, in the PMOS transistor, the magnitude of the difference (the shift amount in the negative direction) exceeded 200 mV. In contrast to this, on the conditions 41 and 42 according to examples of the present invention, the shift direction in the NMOS transistor was the positive direction (in other words, the threshold value increased), and the shift amount (magnitude of difference) in the negative direction in the PMOS transistor was suppressed to be about 50 mV. This indicates that a large mount of nitrogen diffuses to proximity to the substrate to act as positive fixed charge during thermal nitridation on the condition 46, whereas such a disadvantage does not occur on the conditions 41 and 42.

### EXAMPLE 7

In the seventh experiment, the relation between the conditions of post-annealing and the nitrogen profile was examined. Specifically, samples were fabricated on four kinds of conditions as in the first experiment, and their nitrogen profiles were measured by SIMS. Fabrication conditions (manufacturing methods) of the samples are shown in Table 3. The thickness of the SiO₂ film was 0.85 nm. Besides, for the formation of the nitride film, BTBAS was used for all the samples.

TABLE 3

| | | Optical film |
|---|---|---|
| Condition | | thickness of |
| No. | Post-annealing | insulation film |
| 71 | No | 1.51 nm |
| 72 | Only one time in | 1.42 nm |
| | N₂ atmosphere | |
| 73 | 1st time: | 1.52 nm |
| | NO atmosphere, | |
| | 2nd time: | |
| | N₂ atmosphere | |
| 74 | 1st time: | 1.53 nm |
| | O₂ atmosphere, | |
| | 2nd time: | |
| | N₂ atmosphere | |

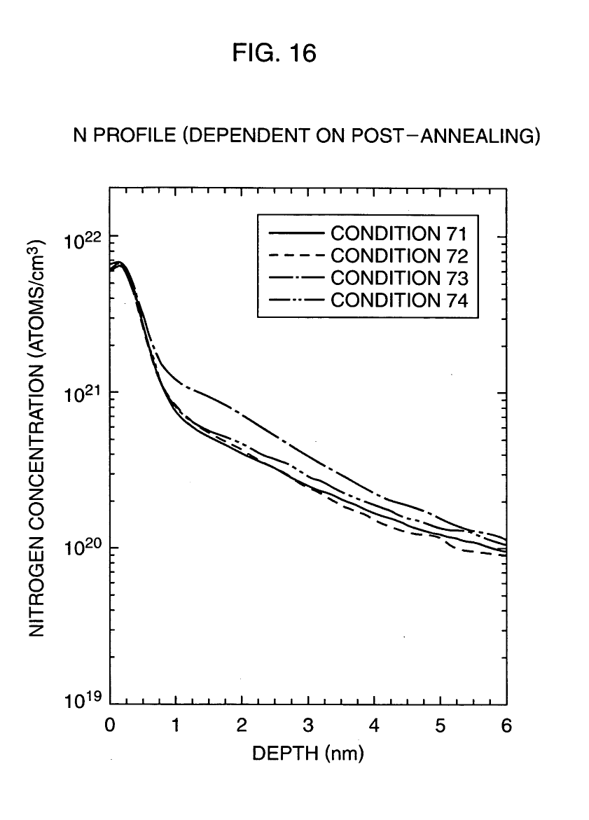

The measurement results on these samples are shown in FIG. 16. As shown in FIG. 16, the steepness of the nitrogen profile does not degrade on any of the conditions 72, 73, and 74 in which various kinds of post-annealing were performed, as compared with that on the condition 71. Therefore, it can be said the performance of post-annealing never degrades characteristics.

### EXAMPLE 8

In the eighth experiment, TDDB (Time Dependant Dielectric Breakdown) life and NBTI (Negative Bias-Temperature In-stability) life were measured. TDDB life increases as the nitrogen concentration in the vicinity of the interface between the gate insulation film and the gate electrode becomes higher, and NBTI life increases as the nitrogen concentration in the vicinity of the interface between the gate insulation film and the silicon substrate becomes lower.

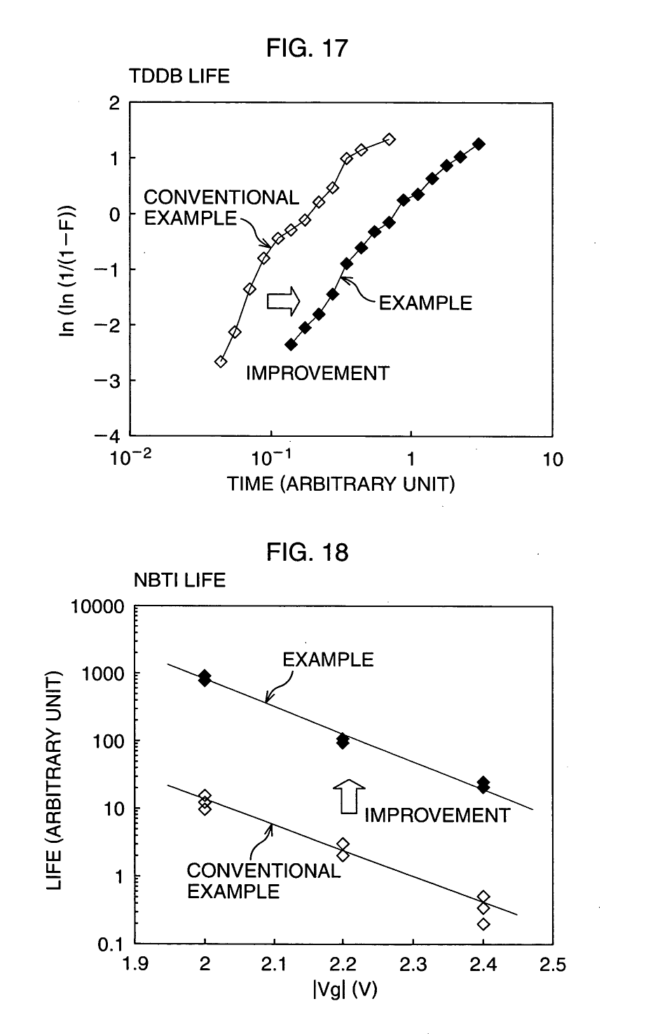

FIG. 17 shows each TDDB life of a comparative example and an example of the present invention, and FIG. 18 shows each NBTI life of a comparative example and an example of the present invention. In the measurement of TDDB life, the gate length of each sample was 5 μm, and the gate width was 20 μm. Further, in the measurement of TDDB life, the failure rate F was found with the temperature set to 125° C. and the gate voltage at 2.8 V. On the other hand, in the measurement of NBTI life, the gate length of each sample was 0.16 μm, and the gate width was 20 μm. Further, the variation amount of drain current was measured with the temperature set to 150° C., so that the time when the value exceeded a predetermined value was regarded as the life of the sample. In short, NBTI life was found with saturation current as a reference.

As shown in FIG. 17, in an example of the present invention, TDDB life was improved by about one digit as compared with a comparative example. Further, as shown in FIG. 18, in an example of the present invention, NBTI life was improved by about two digits as compared with a comparative example. These results indicate that the improvement both in TDDB life and NBTI life, which has been conventionally difficult, becomes possible in an example of the present invention. In other words, the results of these experiments show that the improvement both in TDDB life and NBTI life has been difficult because conventionally the nitrogen profile in the gate insulation film has been gentle, but the use of the gate insulation film with a steep nitrogen profile as in the present invention enables the improvement both in TDDB life and NBTI life.

According to the present invention, without nitriding the surface of a first insulation film, a second insulation film composed of a nitride can be formed over the first insulation film. Therefore, it is possible to reduce the leak current while suppressing an intentional increase in nitrogen concentration in the vicinity of the interface between a gate insulation film and a semiconductor substrate. This results in a steep nitrogen profile in the gate insulation film, which makes it possible to suppress the variation in threshold value and the decrease in mobility.

The present embodiments are to be considered in all respects as illustrative and no restrictive, and all changes which come within the meaning and range of equivalency of the claims are therefore intended to be embraced therein. The invention may be embodied in other specific forms without departing from the spirit or essential characteristics thereof.

1. A semiconductor device, comprising:
a semiconductor substrate;
a gate insulation film formed over said semiconductor substrate; and
a gate electrode formed over said gate insulation film,
said gate insulation film comprising a first insulation film, and a second insulation film formed over said first insulation film and composed of a nitride containing carbon.

2. The semiconductor device according to claim 1, wherein said second insulation film is a silicon nitride film.

3. The semiconductor device according to claim 1, wherein said first insulation film is one kind selected from a group consisting of a silicon oxide film and a silicon oxynitride film.

4. The semiconductor device according to claim 1, wherein said gate insulation film comprises a high dielectric constant film formed between said first insulation film and said second insulation film.

5. The semiconductor device according to claim 4, wherein said high dielectric constant film is one kind selected from a group consisting of a hafnium oxide film, a zirconium oxide film, an aluminum oxide film, a zirconium aluminum oxide film, a lanthanum oxide film, a tantalum oxide film, a titanium oxide film, and an yttrium oxide film.

6. A method for manufacturing a semiconductor device, comprising the steps of:
forming a gate insulation film over a semiconductor substrate; and
forming a conductive film over the gate insulation film,
said step of forming the gate insulation film comprising the steps of forming a first insulation film, and forming over the first insulation film a second insulation film composed of a nitride using a material gas containing carbon.

7. The method for manufacturing a semiconductor device according to claim 6, wherein a silicon nitride film is formed as the second insulation film.

8. The method for manufacturing a semiconductor device according to claim 6, wherein one kind of film selected from a group consisting of a silicon oxide film and a silicon oxynitride film is formed as the first insulation film.

9. The method for manufacturing a semiconductor device according to claim 6, further comprising, between said step of forming the first insulation film and said step of forming the second insulation film, the step of forming a high dielectric constant film over the first insulation film, and
the second insulation film is formed over the high dielectric constant film.

10. The method for manufacturing a semiconductor device according to claim 9, wherein one kind of film selected from a group consisting of a hafnium oxide film, a zirconium oxide film, an aluminum oxide film, a zirconium aluminum oxide film, a lanthanum oxide film, a tantalum oxide film, a titanium oxide film, and an yttrium oxide film is formed as the high dielectric constant film.

11. The method for manufacturing a semiconductor device according to claim 6, wherein bis (tertiary butyl amino) silane is used as the material gas containing carbon.

12. The method for manufacturing a semiconductor device according to claim 6, further comprising, between said step of forming the gate insulation film comprises and said step of forming the conductive film, the step of performing post-annealing on the gate insulation film.

13. The method for manufacturing a semiconductor device according to claim 12, wherein said step of performing the post-annealing comprises the step of performing annealing in one kind of atmosphere selected from a group consisting of an oxidizing atmosphere and an oxynitriding atmosphere.

14. The method for manufacturing a semiconductor device according to claim 12, wherein
said step of performing the post-annealing comprises the steps of:
performing a first annealing in one kind of atmosphere selected from a group consisting of an oxidizing atmosphere and an oxynitriding atmosphere at a first temperature; and
performing a second annealing in a nitriding atmosphere at a second temperature higher than the first temperature.

15. The method for manufacturing a semiconductor device according to claim 12, wherein said step of forming the gate insulation film and said step of performing the post-annealing are performed in sequence in a chamber isolated from atmospheric air.

16. A method for manufacturing a semiconductor device, comprising the steps of:
forming a first insulation film over a semiconductor substrate;
forming over the first insulation film a second insulation film composed of a nitride using a material gas containing carbon; and
performing post-annealing on the first and second insulation films,
said step of forming the first insulation film to said step of performing the post-annealing being performed in sequence in a chamber isolated from atmospheric air.

17. An apparatus for manufacturing a semiconductor device, comprising:
a carrier carrying a semiconductor substrate in an atmosphere isolated from atmospheric air;
a first insulation film former forming a first insulation film over the semiconductor substrate;
a second insulation film former forming a second insulation film composed of a nitride using a material gas containing carbon over the first insulation film; and
a heater performing post-annealing on the first and second insulation films,
said first insulation film former, said second insulation film former, and said heater are connected to said carrier.

18. The apparatus for manufacturing a semiconductor device according to claim 17, wherein said second insulation film former forms a silicon nitride film as the second insulation film.

19. The apparatus for manufacturing a semiconductor device according to claim 17, wherein said second insulation film former uses bis (tertiary butyl amino) silane as the material gas containing carbon.

20. The apparatus for manufacturing a semiconductor device according to claim 18, wherein said second insulation film former uses bis (tertiary butyl amino) silane as the material gas containing carbon.
